(19) United States
(12) Patent Application Publication
(10) Pub. No.: US 2010/0123118 A1
(43) Pub. Date: May 20, 2010

(54) LED Epitaxial Wafer with Patterned GaN based Substrate and Manufacturing Method For the Same

(75) Inventors: Jiahui Hu, Shenzhen (CN); Kuo-Hsiung Chu, Shenzhen (CN); Hsuan-Liang Wu, Shenzhen (CN); Chih-Chiang Shen, Shenzhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Shenzhen Century Epitech LEDs Co., Ltd., Shenzhen (CN)

(21) Appl. No.: 12/431,409

(22) Filed: Apr. 28, 2009

(30) Foreign Application Priority Data
Nov. 20, 2008 (CN) 200810217488.8

(51) Int. Cl. H01L 33/00

(52) U.S. Cl. 257/13; 438/29; 257/E33.032; 257/E33.008; 257/E33.068

(57) ABSTRACT

A LED epitaxial-Chip with patterned GaN based substrate is provided. The LED epitaxial-Chip includes a substrate, a butter layer formed on the substrate, unintentional doped intrinsic GaN layer formed on the substrate, n-GaN layer formed on the substrate, InGaN active layer formed on the substrate, multiple quantum well formed on the substrate; and p-GaN layer formed on the sapphire substrate. The substrate has DBR reflection layer formed thereon. The DBR reflection layer is layered structure grown by two materials having different refractive index periodically alternate. The reflection layer forms at least two spaced patterned structures on the substrate. A manufacturing method of LED epitaxial-Chip with patterned GaN based substrate is also provided.

### FIELD OF THE INVENTION

The present invention relates to a compound semiconductor epitaxial wafer, and more particularly pertains to a light emitting diode epitaxial wafer with patterned GaN based substrate and a manufacturing method therefor.

### BACKGROUND OF THE INVENTION

Light emitting diode (LED) is a solid-state device with ability to light generating, which can directly make electric energy transform into visible light and radiant energy. LED has long work life, high luminous efficiency, light weight, small size, low cost and non-polluting and a series of advantages. LED now has been widely used in large screen display in and out of the hall, backlight display, illumination, ornament, traffic signal light, and so on. Gallium nitride is a mature material used to manufacture blue, green, purple, and ultraviolet light LED. A research of Gallium nitride begins in the 30s of the 20th Century. Someone found that method of growing GaN buffer layer at low temperature can enhance quality of GaN epitaxial film, and manufacture high brightness blue LED using GaN material.

Nowadays, Epitaxial LED with GaN based material has achieved an improvement, and are widely used in a variety of fields. However, there are two problems to be solved in the following: Firstly, no proper substrate, lattice mismatch, thermal mismatch affect manufacturing of GaN material. Decreasing defect density is an important factor for improving properties and life of GaN based light emitting elements. GaN film growing on lattice-mismatched Sapphire or lattice-mismatched SiC is columnar material composed of much hexagonal crystal having a size of about 1 μm and a dislocation density of 10⁹/cm2. Secondly, a serious problem in improving light-extraction efficiency of LEDs is Total Internal Reflection (TIR). GaN and air has an index of refraction 2.5 and 1 respectively, a critical angle of lights generated by InGaN/GaN active layers capable of being transmitted out is only 23 degree. Light internal reflected are repeatedly transmitted at an interface between semiconductor and outer medium or by plane reflector. Light-extraction efficiency is decreased because of crystal surface loss and resorption of active area, which greatly affects external quantum efficiency of GaN based LED.

For decreasing defect density and improving quality of GaN epitaxial layer, high quality GaN epitaxial film are manufactured by using epitaxial lateral overgrowth (ELO). That is, firstly, GaN layer having a thickness of 1 to 2 μm grows on c-Al2O3. Secondly, SiO2, SiC or SiN non-crystal film are deposited on the GaN layer and act as mask. The iO2, SiC or SiN non-crystal film is processed to form a strip-shaped or other shape window by standard light etching. Then, a second epitaxial growing is occurred on the GaN layer. GaN layer on window area becomes crystallon, and epitaxial growing does not occur on non-crystal mask area. When epitaxial GaN layer has an enough thickness, lateral epitaxial growth of GaN layer in window area covers mask. Dislocation density of GaN on mask is obviously decreased.

There are plenty of researches related to improving light-extraction efficiency of LED. For example, someone manufactures nano coarse layer on top p-GaN of GaN based LED by laser radicalization. After surface roughening, roughness of p-GaN is increased from 2.7 μm to 13.2 μm. When applied to 20 mA electrical current, brightness of elements treated by roughening are enhanced 25%. There are some researches related to improving light-extraction efficiency using roughening. Primary method includes roughening, wafer bonding, and laser lift-off of GaN from Sapphire Substrate.

Above-mentioned methods simply improve one property of LED, such as quality of GaN, light-extraction efficiency of GaN based LED. The mentioned methods can not improve problems such as low quality of GaN epitaxial and low light-extraction efficiency of GaN light emitting elements.

### SUMMARY OF THE INVENTION

It is therefore an object of the present invention to provide light emitting diode epitaxial wafer with patterned GaN based substrate, which has high quality, and high light-extraction efficiency.

It is therefore another object of the present invention to provide a manufacturing method of light emitting diode epitaxial wafer with patterned GaN based substrate, which has high quality, and high light-extraction efficiency.

In one aspect, to achieve the object of the present invention, a LED epitaxial wafer with patterned GaN based substrate is provided. In a preferred embodiment, the LED epitaxial wafer includes a substrate, a butter layer formed on the substrate, unintentional doped intrinsic GaN layer formed on the substrate, N-GaN layer formed on the substrate, InGaN active layer formed on the substrate, multiple quantum well formed on the substrate; and P-GaN layer formed on the sapphire substrate. The substrate has DBR reflection layer formed thereon. The DBR reflection layer is layered structure grown by two materials having different refractive index periodically alternate. The reflection layer forms at least two spaced patterned structures on the substrate.

In a further embodiment, the patterned structure is strip shape, regular hexagonal, square, regular trigon or rhombic. A distance between neighboring patterned structures is about from 2 to 20 um. A width of the patterned structure is about from 2 to 20 um. The DBR reflection layer is formed by SiO₂ and SiON or SiC and SiN₄ grown periodically alternately. Cycle times of the DBR reflection layer alternate is about from 3 to 20 times. Each layer of the DBR reflection layer has a thickness of about 50 to 100

In another aspect, to achieve the object of the present invention, a manufacturing method of LED epitaxial-Chip with patterned GaN based substrate is provided. The manufacturing method comprises the steps of: plating a DBR reflection layer on a substrate by plasma-enhanced chemical-vapor deposition; etching the DBR reflection layer to form a patterned structure by; taking out the pattern substrate and rinsing the patterned substrate about 3-60 minutes using deinonized water to obtain a cleanly patterned substrate; pretreating the patterned substrate at a temperature of about 900-1200 centigrade and in a hydrogen atmosphere by using metal organic chemical vapor deposition; decreasing temperature of the sapphire substrate to a growth temperature of low-temperature nucleation layer at 450 to 600° C., and making a GaN or AlN buffer layer having thickness of about 10-60 μm grown; making unintentional doped intrinsic GaN layer having a thickness of 0.5-3 um and a magnesium doped n-GaN layer having a thickness of about from 0.5 to 3 um orderly grown on the low temperature butter layer at a temperature of 950-1100° C., and making InGaN/GaN multiple quantum well having 3-10 periods grown in nitrogen atmosphere and at a temperature of 650-850° C., and making magnesium doped AlGaN layer having a thickness of about from 20 to 200 μm and magnesium doped p-GaN layer having a thickness of about from 100 to 500 nm are orderly grown at a temperature of 800-1100° C.; annealing the epitaxial wafer grown by complete at a temperature of 700-850° C. in a nitrogen atmosphere about 10-20 minutes.

According to the present invention, the DBR reflection layer is layered structure made of two different refractive index grown by periodically alternately. The DBR reflection layer is disposed between the active layer and the sapphire substrate, which can make light incident on the sapphire substrate reflect back to the upper surface using DBR reflection layer. Therefore, light-extraction efficiency of LED is greatly enhanced, and thus external quantum efficiency of LED is enhanced.

### BRIEF DESCRIPTION OF THE DRAWINGS

To better understand the other features, technical concepts and objects of the present invention, one may clearly read the description of the following preferred embodiments and the accompanying drawings, in which:

FIG. 1 is a schematic sectional view of a LED epitaxial wafer with patterned GaN based substrate according to a preferred embodiment according to the present invention;

FIG. 2 is a schematic view of regular hexagonal pattern structure formed on the substrate according to a preferred embodiment according to the present invention;

FIG. 3 is a schematic view of regular triangle pattern structure formed on the substrate according to a preferred embodiment according to the present invention;

FIG. 4 a schematic view of square pattern structure formed on the substrate according to a preferred embodiment according to the present invention;

FIG. 5 a schematic view of rhombic pattern structure formed on the substrate according to a preferred embodiment according to the present invention;

FIG. 6 a schematic view of strip-shaped pattern structure formed on the substrate according to a preferred embodiment according to the present invention.

### DETAILED DESCRIPTION OF THE INVENTION

The LED epitaxial wafer will be described in detail with the following FIG.S and embodiments. It is understood that the following detailed embodiments are used to explain the present invention, and not limited the present invention.

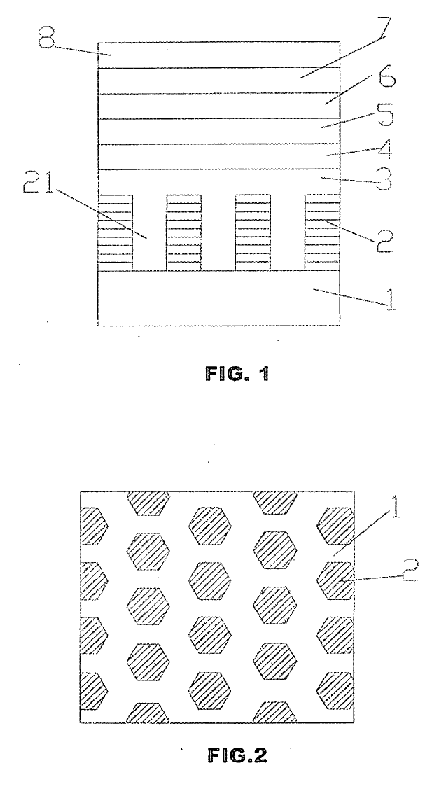

Referring to FIG. 1, a LED epitaxial wafer with patterned GaN based substrate according to a preferred embodiment of the present invention is provided. The LED epitaxial wafer includes a sapphire substrate 1. It is understood that the sapphire substrate 1 may be other substrate such as SiC substrate or Si substrate. There are unintentional doped intrinsic GaN layers 3 formed on the sapphire substrate 1, n-GaN layer 4, InGaN active layer 5, multiple quantum well 6 and p-GaN layer 7, all of which are formed on the sapphire substrate 1. The sapphire substrate 1 has DBR reflection layer 2 formed thereon. The DBR reflection layer 2 is layered structure grown periodically alternate by two materials having different refractive index. The reflection layer 2 forms at least two spaced patterned structures on the sapphire substrate 1. The space between patterned structures is sapphire window area 21. The patterned structures may be strip shape, regular hexagonal, square, regular trigon or rhombic. Referring to FIG. 2˜FIG. 6, the patterned structures may be plurality of window areas formed. GaN epitaxial layer may epitaxial overgrow from the window area 21. When the GaN epitaxial layer covers the window area 21, the GaN epitaxial layer is formed via epitaxial lateral overgrowth at sufficient speed ratio of lateral speed comparing to longitudinal speed until the GaN layers 3 are connected together so as to restrain the GaN layers 3 to become a core on the mask area of the reflection layer 2.

The reflection layer 2 is made of SiO₂ and SiON, which are formed by periodically alternate. It is not easy to become a core no matter what the Ga atom or the N atom is due to difference of bond energy. Ga atom and the N atom may be scattered or be gasified again so as to grow selectedly. Because growth direction of the crystal is perpendicular to original dislocation direction of crystal and the mask layer blocks spread of dislocation, this epitaxial growth method can greatly decrease dislocation density of epitaxial layer and improve quality of GaN epitaxial film. Simultaneously, light emitted from active area of InGaN/GaN multiple quantum well of LED is emitted to an upper and lower surfaces. It is necessary to make light incident downwardly reflect to the upper surface. In this embodiment, the DBR reflection layer 2 is layered structure is layered structure grown periodically alternate by two materials having different refractive index. The DBR reflection layer 2 is disposed between the active layer 5 and the sapphire substrate 1, which can make light incident on the sapphire substrate 1 reflect back to the upper surface using DBR reflection layer 2. Therefore, light-extraction efficiency of LED is greatly enhanced, and thus external quantum efficiency of LED is enhanced.

The epitaxial film with patterned sapphire substrate is manufactured using the following method. The method includes the following steps.

Firstly, a SiO₂ layer having a thickness of 50 to 100 μm is formed on the sapphire substrate by plasma-enhanced chemical-vapor deposition. The SiO2 layer is defined as a first plating layer. A SiON layer having a thickness of 50 to 100 μm is plated on the first plating layer. The SiON layer is defined as a second plating layer. The first plating layer and the second plating layer are plated by cycle and repeatedly about 3 to 30 times. Therefore, the DBR reflection layer arranged by SiO₂ and SiON or arranged by SiC and SiN4 are formed on the sapphire substrate. To obtain better reflection effect for light incident on active area of LED, a thickness of each layer of the DBR reflection layer is about λ/4n, in which λ is wavelength of light, and n is refraction index. In theory, higher reflectivity is, larger the period of the DBR reflection layer is. However, a proper period of the DBR reflection layer is determined according to cost in reality.

Secondly, a strip-shape, regular hexagonal, square, regular trigon or rhombic shape is formed on the sapphire substrate with the DBR reflection layer by using photo etching until the sapphire substrate is exposed out. A width a of the shape defined as is 2 to 20 um. A distance between neighboring shapes defined as b is 2 to 20 um. A width a of the shape and distance b between neighboring shapes is important. Value of a and b are too small, or scale of value of a and b is unharmonious, which all affect quality of lateral epitaxial growth of GaN crystal film, therefore affect quality of GaN epitaxial film and light-extraction efficiency of the GaN based LED.

Thirdly, the sapphire substrate is taken out and is rinsed using deinonized water about from 3 to about 60 to obtain a cleanly sapphire shaped substrate.

Fourthly, the sapphire substrate is pretreated at a hydrogen atmosphere and at a temperature of about 900-1200 centigrade by using metal organic chemical vapor deposition.

Fifthly, decreasing temperature of the sapphire substrate to a growth temperature of low-temperature nucleation layer, which is from 450 to 600° C. A low-temperature GaN or AlN low-temperature buffer layer having a thickness of about 10 to about 60 μm grow at low temperature.

Sixthly, unintentional doped intrinsic GaN layer having a thickness of 0.5 to 3 um and a doped Si n-GaN layer having a thickness of 0.5 to 3 um are orderly grown on the low temperature butter layer at a temperature of 950-1100° C. Then, InGaN/GaN multiple quantum well having 3 to 10 periods is grown in nitrogen atmosphere and at a temperature of 650-850° C. After that, a doped magnesium AlGaN layer having a thickness of 20 to 200 μm and a doped magnesium p-GaN layer having a thickness of 100 to 500 nm are orderly grown at a temperature of 800-1100° C.

Seventhly, the epitaxial wafer is annealed at a temperature of 700-850° C. in a nitrogen atmosphere. The epitaxial wafer with sapphire substrate manufactured by the above method has high quality and high light-extraction efficiency.

### EXAMPLE ONE

Referring to FIG. 2, the patterned structure according to an embodiment of the present invention is regular hexagonal. A width of the patterned structure defined as a is 6 um. A distance between neighboring patterned structures defined as b is 4 um. Cycle times of the SiO2 and SiON alternate is eight. A width of each alternate layer of the SiO2 and SiON are 58 μm and 64 μm, respectively.

### EXAMPLE TWO

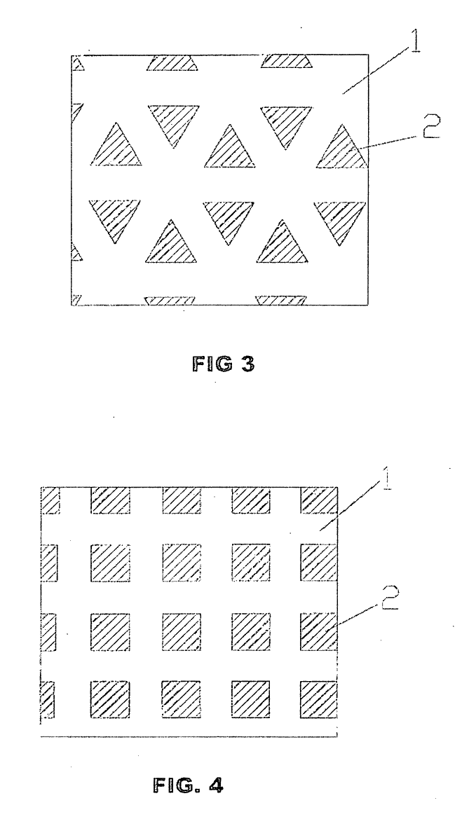

Referring to FIG. 3, the patterned structure according to embodiment of the present invention is regular trigon. A width of the patterned structure defined as a is 3 um. A distance between neighboring patterned structures defined as b is 2 um. Cycle times of the SiO2 and SiON alternate is sixteen. A width of each alternate layer of the SiO2 and SiON are 68 μm and 75 μm, respectively.

### EXAMPLE THREE

Referring to FIG. 4, the patterned structure according to embodiment of the present invention is square. A width of the patterned structure defined as a is 10 um. A distance between neighboring patterned structures defined as b is 6 um. Cycle times of the SiO2 and SiON alternate is four. A width of each alternate layer of the SiO2 and SiON are 58 μm and 64 μm, respectively.

### EXAMPLE FOUR

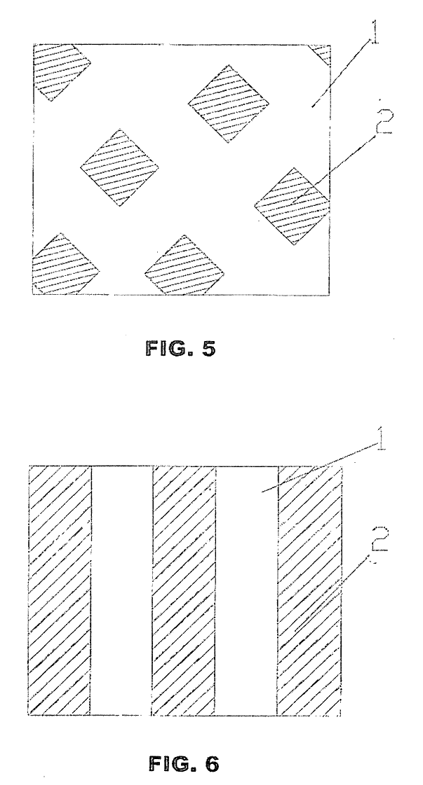

Referring to FIG. 5, the patterned structure according to embodiment of the present invention is rhombic. A width of the patterned structure defined as a is 4 um. A distance between neighboring patterned structures defined as b is 6 um. Cycle times of the SiO2 and SiON alternate is eight. A width of each alternate layer of the SiO2 and SiON are 68 μm and 75 μm, respectively.

### EXAMPLE FIVE

Referring to FIG. 6, the patterned structure according to embodiment of the present invention is strip-shaped. A width of the patterned structure defined as a is 3 um. A distance between neighboring patterned structures defined as b is 3 um. Cycle times of the SiC and SiN₄ alternate is six. A width of each alternate layer of the SiC and SiN₄ are 58 μm and 64 μm, respectively.

### EXAMPLE SIX

Referring to FIG. 2, the patterned structure according to embodiment of the present invention is regular hexagon. A width of the patterned structure defined as a is 15 um. A distance between neighboring patterned structures defined as b is 15 um. Cycle times of the SiC and SiN₄ alternate is three. A width of each alternate layer of the SiC and SiN₄ are 70 μm and 85 μm, respectively.

What is claimed is:

1. A LED epitaxial wafer with patterned GaN based substrate, comprising:
a substrate;
a buffer layer formed on the substrate;
unintentional doped intrinsic GaN layer formed on the substrate;
n-GaN layer formed on the substrate;
InGaN/GaN active layer formed on the substrate;
multiple quantum well formed on the substrate; and
p-GaN layer formed on the substrate;
wherein the substrate has DBR reflection layer formed thereon, the DBR reflection layer is layered structure grown by two materials having different refractive index periodically alternate, the reflection layer forms at least two spaced patterned structures on the substrate.

2. According to the LED in claim 1, wherein said patterned structure is strip shape, regular hexagonal, square, regular trigon or rhombic.

3. According to the LED in claim 2, wherein a distance between neighboring patterned structures is about from 2 to 20 um.

4. According to the LED in claim 3, wherein a width of the patterned structure is about from 2 to about 20 um.

5. According to the LED in claim 4, wherein the DBR reflection layer is formed by SiO₂ and SiON or SiC and SiN₄ grown periodically alternately.

6. According to the LED in claim 5, wherein cycle times of the DBR reflection layer alternate is about from 3 to 20 times.

7. According to the LED in claim 1, wherein each layer of the DBR reflection layer has a thickness of about from 50 to 100 μm.

8. A manufacturing method of LED epitaxial wafer with patterned GaN based substrate, comprising:
plating a DBR reflection layer on a substrate by plasma-enhanced chemical-vapor deposition;
etching the DBR reflection layer to form a patterned structure by photo etching;
taking out the pattern substrate and rinsing the patterned substrate about 3-60 minutes using deinonized water to obtain a cleanly patterned substrate;
pretreating the patterned substrate at a temperature of about 900-1200 centigrade and in a hydrogen atmosphere by using metal organic chemical vapor deposition;
decreasing temperature of the sapphire substrate to a growth temperature of low-temperature nucleation layer at 450 to 600° C., and making a GaN or AlN low-temperature buffer layer having thickness of about 10-60 μm grown;
making unintentional doped intrinsic GaN layer having a thickness of about 0.5 to 3 um and a magnesium doped n-GaN layer having a thickness of 0.5 to 3 um orderly grown on the low temperature butter layer at a temperature of 950-1100° C., and making InGaN/GaN multiple quantum well having 3 to 10 periods grown in nitrogen atmosphere and at a temperature of 650-850° C., and making magnesium doped AlGaN layer having a thickness of 20-200 μm and magnesium doped p-GaN layer having a thickness of 100 to 500 nm are orderly grown at a temperature of 800 to 1100° C.;
annealing the epitaxial wafer grown by complete at a temperature of 700 to 850° C. in a nitrogen atmosphere about 10 to 20 minutes.

9. According to the manufacturing method of LED epitaxial wafer with patterned GaN based substrate in claim 8, wherein the DBR reflection layer is formed by SiO₂ and SiON or SiC and SiN₄ grown periodically alternately.

10. According to the manufacturing method of LED epitaxial wafer with patterned GaN based substrate in claim 9, wherein cycle times of the DBR reflection layer alternate is about from 3 to 20 times.

11. According to the manufacturing method of LED epitaxial wafer with patterned GaN based substrate in claim 10, wherein each layer of the DBR reflection layer has a thickness of about from 50 to 100 μm.

12. According to the manufacturing method of LED epitaxial wafer with patterned GaN based substrate in claim 8, wherein the patterned structure is strip shape, regular hexagonal, square, regular trigon or rhombic.

13. According to the manufacturing method of LED epitaxial wafer with patterned GaN based substrate in claim 12, wherein a distance between neighboring patterned structures is about from 2 to 20 um.

14. According to the manufacturing method of LED epitaxial-Chip with patterned GaN based substrate in claim 12, wherein a width of the patterned structure is about from 2 to 20 um.
